(19) United States
(12) Patent Application Publication
(10) Pub. No.: US 2025/0246556 A1
(43) Pub. Date: Jul. 31, 2025

(54) APPARATUSES FOR REDUCING PIN-TO-PIN INTERFERENCE IN PHYSICAL PROCESSORS

(71) Applicant: PLUME DESIGN, INC., Palo Alto, CA (US)

(72) Inventors: Yun-Ping HUANG, Santa Clara, CA (US); Miroslav SAMARDZIJA, Mountain View, CA (US); Liem Hieu Dinh VO, San Jose, CA (US)

(21) Appl. No.: 18/428,246

(22) Filed: Jan. 31, 2024

(51) Int. Cl. H01L 23/552; H01L 23/367

(52) U.S. Cl. CPC H01L 23/552; H01L 23/3675

(57) ABSTRACT

The disclosed apparatus is configured to include (i) a shield can configured to reduce electromagnetic interference between components inside the shield can and components outside the shield can; (ii) a physical processor inside the shield can that includes a first region and a second region; and (iii) one or more spacer pads situated between and in contact with the shield can and the first region, but not in contact with the second region. Various other embodiments and modifications are also disclosed.

### BACKGROUND

In some electronic devices, memory components and radio frequency components can sometimes operate within the same frequency band (e.g., at approximately 2.4 GHz) which can lead to undesired radio-frequency coupling that reduces the range and sensitivity of radio transmission components. Even within a single physical processor, pins of the chip that are responsible for transmitting these signals can cause interference with each other. Heat sinks, thermal pads, and other components that are typically used in heat management for physical processors can worsen the problem thanks to inductive coupling to on-chip noise sources (e.g., one particular set of pins), causing the heat management components to convey the radio frequency signals to other areas of the physical processor. Indeed, some chip manufacturers recommend a minimum clearance between a physical processor and a conductive object such as a shield can in order to minimize pin-to-pin interference in the physical processor.

### BRIEF DESCRIPTION OF THE DRAWINGS

The accompanying drawings illustrate several example implementations and are a part of the specification. Together with the following description, these drawings demonstrate and explain various principles of the present disclosure.

FIG. 1 is a block diagram of an example device for reducing pin-to-pin interference in physical processors.

FIG. 2 is an example schematic diagram of an example physical processor configured to minimize pin-to-pin interference.

FIG. 3 is an example schematic diagram of an additional configuration for an example physical processor to minimize pin-to-pin interference.

FIG. 4 is a schematic diagram of an example shield can lid configured to minimize pin-to-pin interference in physical processors enclosed by a shield can.

FIG. 5 is an additional schematic diagram of an example shield can lid configured to minimize pin-to-pin interference in physical processors enclosed by a shield can.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to apparatuses and systems for reducing pin-to-pin interference in physical processors. Radio frequency signals and currents used by many electronic devices for communicating with other devices typically involve high frequencies, such as 2.4 GHz, though any suitable frequency may be used. In some examples, the radio frequency signals and corresponding radio frequency radiation may involve frequencies greater than 2.4 GHz. Currents oscillating at these frequencies may cause capacitive coupling (sometimes referred to as parasitic capacitance) between two closely spaced conductors, such as the materials of the processor itself and the metal of a shield can that is used to electromagnetically isolate an electronic component to prevent interference with other components of the device. If these conductive elements are placed too closely (e.g., if a shield can lid is placed too close to a processor, or if thermal pads are used to help conduct heat from the processor to the shield can), then the capacitive coupling between one area of the processor to the shield can and back to another area of the processor can cause pin-to-pin interference. In examples where data transfer frequencies across one set of pins are similar to or within the same frequency band as those used by a different set of pins (such as 2.4 GHz DDR memory and 2.4 GHz radio transmission), the functioning of one, either, or both of the associated components can be reduced. In the previous example, data transfer to the DDR memory can cause interference that reduces a sensitivity of a radio transmission component (such as a wireless network interface), slowing down data transfer rates and reducing the effective range of the radio transmission component.

As will be described in greater detail below, thermal conduction pads (sometimes called “thermal transfer pads” or simply “thermal pads”) and/or radio-frequency absorber pads placed over certain areas of a chip but not others can reduce or eliminate parasitic coupling to the pads and/or a shield can used to protect the processor and/or other components from radio frequency interference by allowing for sufficient physical space between noise sources (such as DDR pin outs) and materials that can conduct the interference to other areas of the chip (such as shield can lids and/or the aforementioned pads). By not placing thermal pads or other spacers over chip regions that generate electromagnetic interference, manufacturers of electronic devices can ensure that physical processors in their devices are appropriately shielded from other components in the device and provided with sufficient cooling for proper operation while also avoiding pin-to-pin interference on the processor itself. Additional modifications to various components such as recessed areas of shield can lids placed over interference sources can increase the distance between the shield can lid and the interference source, further reducing conduction of any unwanted interference to other areas of the physical processor.

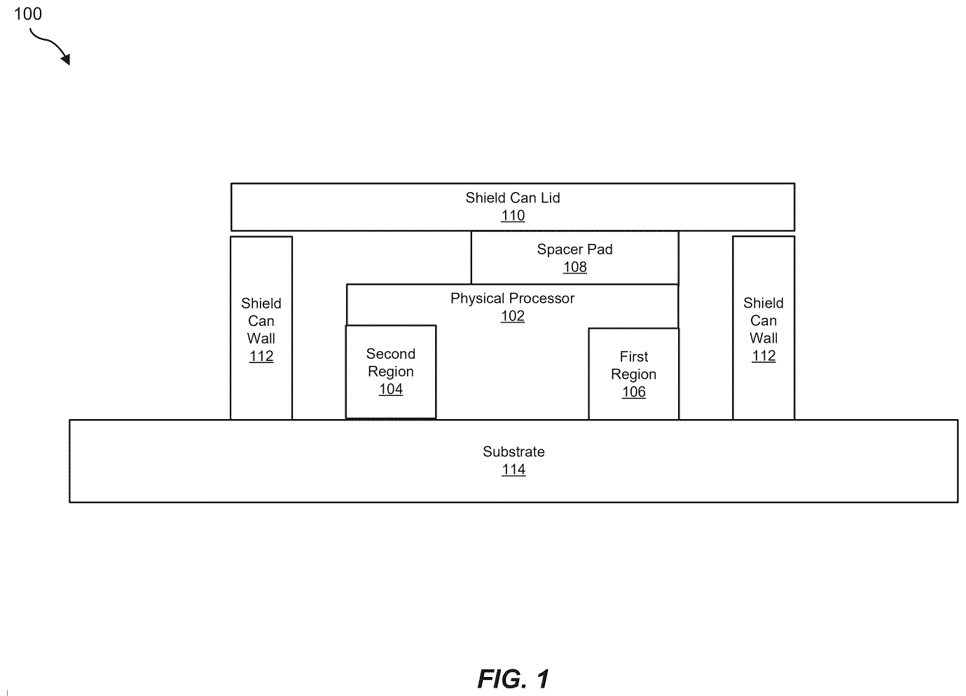

FIG. 1 is a side-view schematic diagram of an example physical processor assembly 100 that consists of a physical processor contained within a shield can with spacer pads placed to conduct heat from the physical processor to the shield can. As shown in this example, a physical processor 102 is supported on a substrate 114, such as a PCB layer. Physical processor 102 has a first region 106 and a second region 104. Second region 104 can be a source of electromagnetic interference, such as a memory interface region of physical processor and/or memory interface pinouts that produce electromagnetic interference when in operation. First region 106 can be a region of the chip that needs protection from electromagnetic interference, such as a radio transmission region, radio transmitter control region, or pinouts connected to a radio transmission component situated outside the shield can. In some examples, both first region 106 and second region 104 can operate within a same frequency band, such as within a 2.4 GHz frequency band.

The shield can includes a shield can lid 110 that covers physical processor 102 and is supported by shield can walls 112. In some examples, shield can lid 110 can be materially contiguous with shield can walls 112. In other examples, shield can lid 110 can be supported by spring fingers that allow for some air to pass through the shield can while still providing electromagnetic isolation between physical processor 102 and other components of the larger device. In some embodiments, shield can lid 110 can be a heat sink and/or a region of a heat sink intended to receive heat from a physical processor.

Spacer pads 108 are placed between and in contact with physical processor 102 and shield can lid 110 to help conduct heat away from physical processor 102 and into shield can lid 110 for dissipation. Spacer pads 108 can also help keep space between shield can lid 110 and components of physical processor 102 (such as second region 104) that should be kept a minimum distance from shield can lid 110 to avoid unwanted electromagnetic coupling. In some examples, spacer pad 108 can include one or more thermally conductive pads designed to conduct heat away from physical processor 102. Additionally or alternatively, spacer pad 108 can included one or more absorber pads that are capable of blocking radio-frequency electromagnetic interference. Various pad configurations will be described in greater detail below.

In some examples, the term “memory,” “memory device,” or “memory component” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage device. In some embodiments, a memory device may operate at a 2.4 GHz data transfer rate or at any other suitable frequency.

The term “physical processor” as used herein generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

The term “shield can” as used herein generally refers to any component configured to electromagnetically isolate one portion of an electronic device from other components. For example, a physical processor can be enclosed within a shield can to prevent electromagnetic interference from or with other components of an electronic device. Shield cans can be formed from any suitable material, such as copper, aluminum, composite materials, alloys, or any other material with properties suitable for electromagnetic isolation. In some examples, a shield can can include a shield can lid that allows the shield can to fully enclose the shielded electronic component. In other examples, a shield can can simply consist of four walls without a lid. In embodiments where the shield can has a lid, the lid can be physically contiguous (i.e., formed from a single sheet of material) with the walls. Alternatively, the lid can be a separate component that is glued, welded, clipped, or pressed into place by additional components.

The term “spacer pad” generally refers to any compound, composite, material layer, etc. that is configured to occupy the space between a physical processor and another surface such as a heat sink or shield can lid. In some examples, a spacer pad can be designed to be thermally conductive to aid in cooling the physical processor by conducting heat away from the physical processor and into a dissipative component such as a shield can lid or heat sink; such pads are referred to herein as “thermal pads” or “thermal transfer pads.” In other examples, a spacer pad can be configured to absorb radio frequency (RF) radiation and prevent electromagnetic coupling between components; such pads are referred to herein as “absorber pads,” “RF absorbing pads,” or similar. In some examples, thermal pads can be electrically conductive and thus vulnerable to electromagnetic coupling with sources of interference. To address this issue, in some embodiments, a spacer pad layer can include a number of thermally conductive spacer pads interspersed with RF absorber pads to prevent one region of the spacer pad from electromagnetically coupling to another region of the spacer pad layer (e.g., another thermal pad), thus reducing the ability of the spacer pad layer to conduct electromagnetic interference from one region to another. In some examples, several spacer pads can be arranged into a spacer pad layer that fills all or a portion of the space between a physical processor and another surface, such as a shield can lid or heat sink. A spacer pad layer can be of any suitable thickness, such as less than 1 mm, 1 mm, 2 mm, 3 mm, 4 mm, or any other suitable thickness.

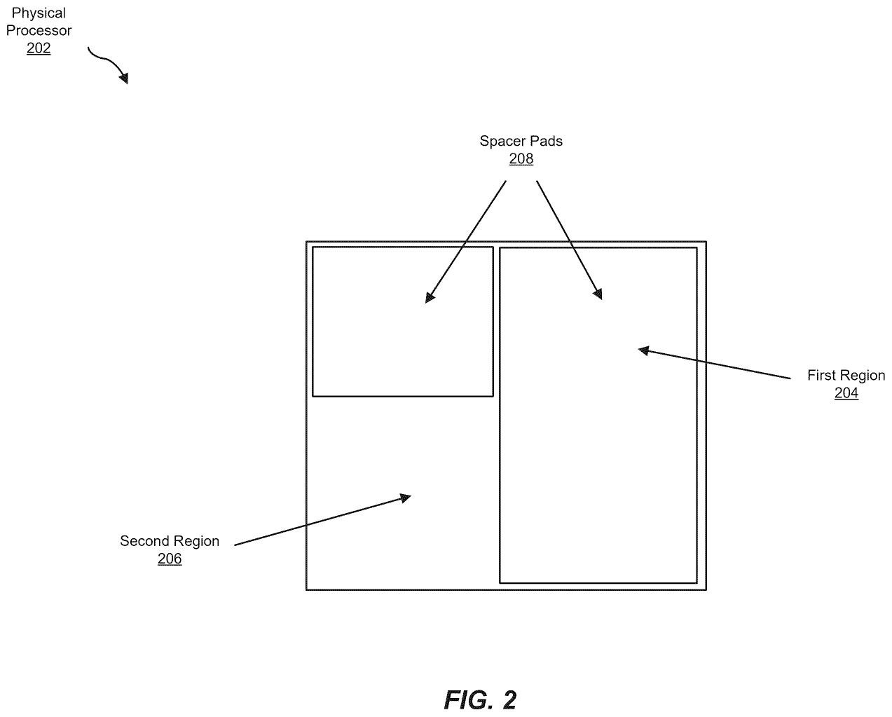

FIG. 2 is a top-view schematic diagram of a physical processor layered with spacer pads. In the example of FIG. 2, physical processor 202 has a first region 204 and a second region 206. Second region 206 can include pinouts that are capable of inductively coupling to metallic components and/or spacer pads, causing interference with other portions of physical processor 202 such as first region 204. To prevent this, spacer pads 208 explicitly do not cover second region 206, thereby providing sufficient distance between the interference-generating parts of second region 206 and materials that could conduct the interference, such as spacer pads 208 or a metallic shield can such as the shield can illustrated in FIG. 1. This configuration of spacer pads can allow the spacer pads to efficiently conduct heat away from physical processor 202 while avoiding capacitive coupling of second region 206 to spacer pads 208 and/or the shield can (which is not illustrated here in FIG. 2). The uncovered portion of physical processor 202 can be of any suitable size or dimension. In some examples, spacer pads 208 may be at least 4 mm away, at least 5 mm away, or any other suitable clearance distance from the interference-generating portions of second region 206. In further examples, spacer pads 208 may cover less than 70%, 75%, 80%, or any other suitable percentage of physical processor 202. Although the uncovered region is roughly square-shaped in this example, the uncovered portion of physical processor 202 can be of any suitable shape, such as a segment of a circle (e.g., a quarter circle) centered on a region that generates interference.

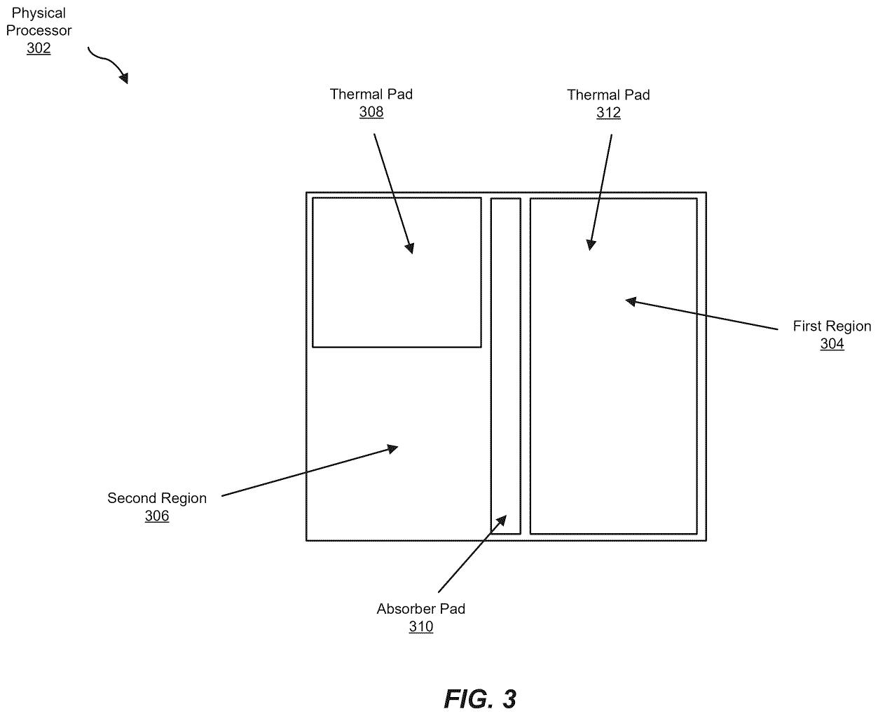

FIG. 3 is a top-down schematic diagram of a physical processor 302 with an alternate arrangement of spacer pads that incorporates an RF absorber pad. In this example, physical processor 302 is layered with thermal pads 308 and 312. However, unlike the previous example, physical processor 302 is also layered with an absorber pad 310 that is situated between thermal pad 308 and thermal pad 312, thus inhibiting thermal pad 308 from capacitively coupling to thermal pad 312. The placement of absorber pad 310 can thus reduce interference between second region 306 and first region 304 by blocking interference generated at second region 306 from capacitively coupling to thermal pad 312 and being conducted to first region 304.

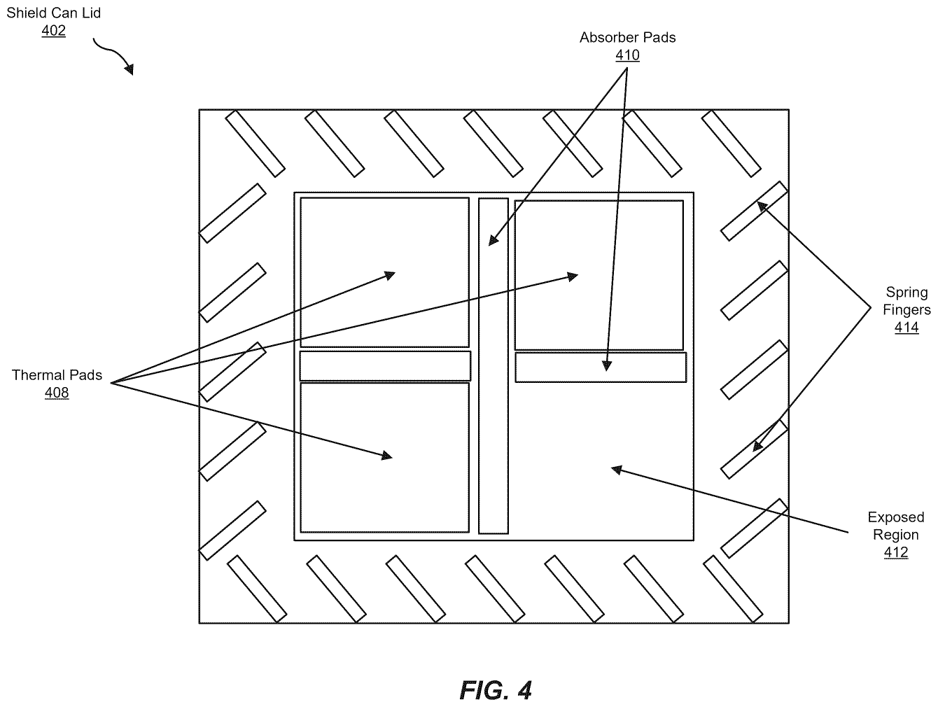

In some examples, the spacer pads may be affixed to a shield can lid or heat sink rather than directly to the physical processor and held in place against the processor when the lid or heat sink is pressed into place. FIG. 4 is a schematic diagram of an example shield can lid 402 configured to minimize pin-to-pin interference between regions of a physical processor enclosed in a shield can. As shown in FIG. 4, shield can lid 402 includes an array of spring fingers 414 that can provide space between the walls of the shield can and shield can lid 402 to allow air to flow through the shield can and cool the physical processor. Shield can lid 402 can also include a set of absorber pads 410 disposed between thermal pads 408. As with the previous examples, thermal pads 408 can be configured to draw heat away from the physical processor to be dissipated by shield can lid 402 and/or a heat sink. Absorber pads 410, which in the example of FIG. 4 are arranged in a crosswise pattern between thermal pads 408, can help prevent different regions of the spacer pad layer from capacitively coupling to each other, thereby reducing the layer's transmission of any electromagnetic interference from one region of the physical processor to another. To further facilitate this insulation against electromagnetic interference, shield can lid 402 includes an exposed region 412 that does not have any absorber pads or thermal pads in contact with it to ensure that there is sufficient space between the second region of the physical processor and any components that might capacitively couple to the second region and cause pin-to-pin interference in the physical processor. Although FIGS. 2-4 illustrate a variety of different layouts for RF absorber pads and thermal pads, some of which are arranged on the physical processor and some of which are arranged on a shield can lid, any suitable arrangement of spacer pads can be used on any suitable surface. For example, the pad layout shown in FIG. 2 could be applied to a shield can lid. The pads would then be pressed into contact with the physical processor when the shield can lid is pressed into place to close the shield can. Similarly, the pad layout illustrated in FIG. 4 could be applied directly to a physical processor and come into contact with a heat sink that is pressed into place against the pad layer.

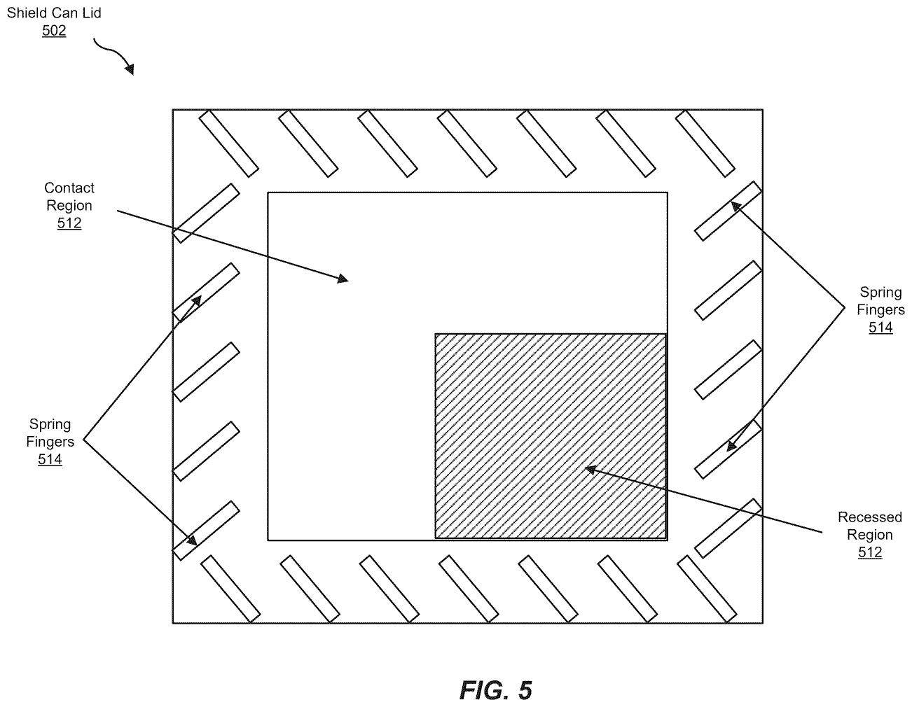

In some embodiments, the underlying shield can lid or heat sink surface can be etched, carved, or recessed in certain areas to further improve clearance between conductive components and sources of electromagnetic interference. FIG. 5 shows an example shield can lid 502 that includes a contact region 512 that is configured to contact a pad layer applied to a physical processor and/or support a pad layer that can be pressed into contact with a physical processor. Shield can lid 502 also includes a recessed region 512 that has been carved, etched, cast, thinned out, or otherwise formed to increase a distance between the material of shield can lid 502 and an interference-generating region of a physical processor without increasing the total height of the shield can. As with shield can lid 402, shield can lid 502 includes spring fingers (illustrated as spring fingers 514) that are configured to come into contact with the walls of a shield can to form an electromagnetic barrier between the component(s) inside the shield can and those outside the shield can.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An apparatus comprising:
a shield can that is configured to reduce electromagnetic interference between components that are inside the shield can and components that are outside the shield can, the shield can comprising shield can walls and a shield can lid;
a physical processor, disposed within the shield can, comprising a first region and a second region; and
one or more spacer pads, disposed between and in contact with the shield can and the first region, and not in contact with the second region.

2. The apparatus of claim 1, wherein the first region comprises a radio receiver control region.

3. The apparatus of claim 1, wherein the second region comprises a memory interface region.

4. The apparatus of claim 1, wherein the one or more spacer pads comprises one or more thermal transfer pads.

5. The apparatus of claim 1, wherein the one or more spacer pads comprises one or more radio-frequency absorber pads.

6. The apparatus of claim 1, wherein the one or more spacer pads are in contact with less than 75% of the physical processor.

7. The apparatus of claim 1, wherein a portion of the shield can lid that is disposed over the second region is recessed to increase a distance between the shield can lid and the second region.

8. The apparatus of claim 1, wherein the shield can lid comprises a heat sink.

9. The apparatus of claim 1, wherein the shield can lid comprises spring fingers configured to contact the shield can walls.

10. The apparatus of claim 1, wherein:
the first region comprises a radio receiver control region;
the second region comprises a memory interface region; and
a radio receiver communicatively coupled to the radio receiver control region and a physical memory communicatively coupled to the memory interface region operate within a same frequency band.

11. A system comprising:
a shield can that is configured to reduce electromagnetic interference between components that are inside the shield can and components that are outside the shield can, the shield can comprising shield can walls and a shield can lid;
a physical memory, disposed outside of the shield can;
a radio transmission component, disposed outside of the shield can;
a physical processor, disposed within the shield can and communicatively coupled to the physical memory and the radio transmission component, the physical processor comprising a first region and a second region; and
one or more spacer pads, disposed between and in contact with the shield can and the first region, and not in contact with the second region.

12. The system of claim 11, wherein the first region comprises a radio receiver control region.

13. The system of claim 11, wherein the second region comprises a memory interface region.

14. The system of claim 11, wherein the one or more spacer pads comprises one or more thermal transfer pads.

15. The system of claim 11, wherein the one or more spacer pads comprises one or more radio-frequency absorber pads.

16. The system of claim 11, wherein the one or more spacer pads are in contact with less than 75% of the physical processor.

17. The system of claim 11, wherein a portion of the shield can lid that is disposed over the second region is recessed to increase a distance between the shield can lid and the second region.

18. The system of claim 11, wherein the shield can lid comprises a heat sink.

19. The system of claim 11, wherein the shield can lid comprises spring fingers configured to contact the shield can walls.

20. The system of claim 11, wherein:
the first region is communicatively coupled to the radio transmission component;
the second region is communicatively coupled to the physical memory; and
the radio transmission component and the physical memory operate within a same frequency band.
